(19) United States
(12) Patent Application Publication
(10) Pub. No.: US 2013/0306145 A1
(43) Pub. Date: Nov. 21, 2013

(54) GLASS SUBSTRATE FOR CU-IN-GA-SE SOLAR CELL AND SOLAR CELL USING SAME

(71) Applicant: ASAHI GLASS COMPANY, LIMITED, Chiyoda-ku (JP)

(72) Inventors: Yu HANAWA, Tokyo (JP); Yutaka Kuroiwa, Chiyoda-ku (JP); Tetsuya Nakashima, Tokyo (JP); Reo Usui, Tokyo (JP); Takeshi Tomizawa, Tokyo (JP); Tomomi Sekine, Tokyo (JP)

(73) Assignee: ASAHI GLASS COMPANY, LIMITED, Chiyoda-ku (JP)

(21) Appl. No.: 13/952,936

(22) Filed: Jul. 29, 2013

Related U.S. Application Data
(63) Continuation of application No. PCT/JP2012/051693, filed on Jan. 26, 2012.

(30) Foreign Application Priority Data
Jan. 28, 2011 (JP) 2011-016475

(51) Int. Cl. H01L 31/0392; C03C 3/087; C03C 3/093

(52) U.S. Cl. CPC H01L 31/03923; C03C 3/093; C03C 3/087
USPC 136/256; 501/67; 501/70

(57) ABSTRACT

A glass substrate for a CIGS solar cell containing specific amounts of SiO₂, Al₂O₃, B₂O₃, MgO, CaO, SrO, BaO, ZrO₂, TiO₂, Na₂O and K₂O, respectively. The glass substrate satisfies the specific requirements regarding MgO+CaO+SrO+BaO, Na₂O+K₂O, MgO/Al₂O₃, (2Na₂O+K₂O+SrO+BaO)/(Al₂O₃+ZrO₂), Na₂O/K₂O, the relation of Al₂O₃ and MgO, and the relation of CaO and MgO, respectively. The glass substrate has a glass transition temperature of 640° C. or higher, an average coefficient of thermal expansion within a range of 50 to 350° C. of 70×10⁻⁷ to 90×10⁻⁷/° C., the temperature (T₄) of 1,230° C. or lower, the temperature (T₂) of 1,650° C. or lower, and a density of 2.7 g/cm³ or less. The glass substrate satisfies the relationship of T₄−T_{L}≧−30° C.

### TECHNICAL FIELD

The present invention relates to a glass substrate for a solar cell having a photoelectric conversion layer formed between glass substrates, and solar cells using the same. In more detail, the present invention relates to a glass substrate for a Cu—In—Ga—Se solar cell having a glass substrate and a cover glass, in which a photoelectric conversion layer comprising an element of Group 11, Group 13 or Group 16 as a main component is formed between the glass substrate and the cover glass, and a solar cell using the same.

### BACKGROUND ART

Group 11-13 and Group 11-16 compound semiconductors having a chalcopyrite structure and Group 12-16 compound semiconductors of a cubic system or hexagonal system have a large absorption coefficient to light in the visible to near-infrared wavelength range. Thus, they are expected as a material for high-efficiency thin film solar cell. Representative examples thereof include Cu(In,Ga)Se₂ (hereinafter referred to as “CIGS” or “Cu—In—Ga—Se”) and CdTe.

In the CIGS thin film solar cell, in view of the matters that it is inexpensive and that its average coefficient of thermal expansion is close to that of the CIGS compound semiconductor, a soda lime glass is used as a substrate, and a solar cell is obtained.

Also, in order to obtain a solar cell with good efficiency, a glass material which withstands a heat treatment temperature of high temperatures has been proposed (see Patent Documents 1 and 2).

### PRIOR ART DOCUMENTS

### Patent Document

Patent Document 1: JP-A-11-135819
Patent Document 2: JP-A-2011-9287

### SUMMARY OF THE INVENTION

### Problems to be Solved By the Invention

A CIGS photoelectric conversion layer (hereinafter referred to as “CIGS layer”) is formed on the glass substrate. However, as disclosed in Patent Documents 1 and 2, in order to fabricate a solar cell with good cell efficiency, a heat treatment at a higher temperature is preferable, and the glass substrate is required to withstand it. In Patent Document 1, a glass composition having a relatively high annealing point has been proposed; however, it is not always said that the invention described in Patent Document 1 has high cell efficiency.

Moreover, it is an object of the process of Patent Document 2 to efficiently diffuse alkali elements with a low concentration which are contained in a high strain point glass into a p-type light absorbing layer by providing an alkali controlling layer. However, a cost is required for a step of providing the alkali controlling layer which should be added, and the diffusion of the alkali elements becomes insufficient due to the alkali controlling layer, so that there is a concern that efficiency decreases.

The present inventors discovered that the cell efficiency could be enhanced by increasing an alkali in the glass substrate in a prescribed range, but there was a problem that the increase in the amount of an alkali incurred lowering of a glass transition temperature (Tg).

On the other hand, in order to prevent peeling of a CIGS layer on a glass substrate during the deposition or after the deposition, the glass substrate is required to have a prescribed average coefficient of thermal expansion.

Furthermore, from the standpoints of production and use of a CIGS solar cell, enhancement in strength and reduction in weight of a glass substrate, good meltability and good formability during production of a sheet glass, and non-devitrification are required.

Thus, in the glass substrate used in the CIGS solar cell, it was difficult to have characteristics of high cell efficiency, high glass transition temperature, a prescribed average coefficient of thermal expansion, high glass strength, low glass density, meltability and formability during production of a sheet glass, and prevention of devitrification in good balance.

An object of the present invention is to provide a glass substrate for a Cu—In—Ga—Se solar cell, having the characteristics of high cell efficiency, high glass transition temperature, a prescribed average coefficient of thermal expansion, high glass strength, low glass density, meltability and formability during production of a sheet glass, and prevention of devitrification in good balance, and a solar cell using the same.

The present invention provides the following glass substrate for a Cu—In—Ga—Se solar cell, and solar cell.

(1) A glass substrate for a Cu—In—Ga—Se solar cell, containing, in terms of mol % on the basis of the following oxides:

from 60 to 75% of SiO₂;

from 1 to 7.5% of Al₂O₃;

from 0 to 1% of B₂O₃;

from 8.5 to 12.5% of MgO;

from 1 to 6.5% of CaO;

from 0 to 3% of SrO;

from 0 to 3% of BaO;

from 0 to 3% of ZrO₂;

from 0 to 3% of TiO₂;

from 1 to 8% of Na₂O; and

from 2 to 12% of K₂O,

wherein MgO+CaO+SrO+BaO is from 10 to 24%,

Na₂O+K₂O is from 5 to 15%,

MgO/Al₂O₃ is 1.3 or more,

(2Na₂O+K₂O+SrO+BaO)/(Al₂O₃+ZrO₂) is 3.3 or less,

Na₂O/K₂O is from 0.2 to 2.0

Al₂O₃≧−0.94MgO+11, and

CaC≧−0.48MgO+6.5,

wherein the glass substrate has a glass transition temperature of 640° C. or higher, an average coefficient of thermal expansion within a range of 50 to 350° C. of from 70×10⁻⁷ to 90×10⁻⁷/° C., a temperature (T₄) at which a viscosity reaches 10⁴ dPa·s of 1,230° C. or lower, a temperature (T₂) at which a viscosity reaches 10² dPa·s of 1,650° C. or lower, a relationship between the T₄ and a devitrification temperature (T_{L}) of T₄−T_{L}≧−30° C., and a density of 2.7 g/cm³ or less.

(2) The glass substrate for a Cu—In—Ga—Se solar cell according to (1), containing, in terms of mol % on the basis of the following oxides:

from 62 to 73% of SiO₂;

from 1.5 to 7% of Al₂O₃;

from 0 to 1% of B₂O₃;

from 9 to 12.5% of MgO;

from 1.5 to 6.5% of CaO;

from 0 to 2.5% of SrO;

from 0 to 2% of BaO;

from 0.5 to 3% of ZrO₂;

from 0 to 3% of TiO₂;

from 1 to 7.5% of Na₂O; and

from 2 to 10% of K₂O,

wherein MgO+CaO+SrO+BaO is from 11 to 22%,

Na₂O+K₂O is from 6 to 13%,

MgO/Al₂O₃ is 1.4 or more,

(2Na₂O+K₂O+SrO+BaO)/(Al₂O₃+ZrO₂) is from 0.5 to 3,

Na₂O/K₂O is from 0.4 to 1.7

Al₂O₃≧−0.94MgO+12, and

CaO≧−0.48MgO+7,

wherein the glass substrate has the glass transition temperature of 645° C. or higher, the average coefficient of thermal expansion within a range of 50 to 350° C. of from 70×10⁻⁷ to 85×10⁻⁷/° C., the temperature (T₄) at which a viscosity reaches 10⁴ dPa·s of 1,220° C. or lower, the temperature (T₂) at which a viscosity reaches 10² dPa·s of 1,630° C. or lower, the relationship between the T₄ and a devitrification temperature (11) of T₄−T_{L}≧−20° C., and the density of 2.65 g/cm³ or less.

(3) The glass substrate for a Cu—In—Ga—Se solar cell according to (1) or (2), wherein MgO/(MgO+CaO+SrO+BaO) is from 0.4 to 0.9.

(4) A solar cell, comprising a glass substrate, a cover glass, and a photoelectric conversion layer of Cu—In—Ga—Se provided between the glass substrate and the cover glass,

wherein at least the glass substrate of the glass substrate and the cover glass is the glass substrate for a Cu—In—Ga—Se solar cell according to any one of (1) to (3).

### ADVANTAGES OF THE INVENTION

The glass substrate for a Cu—In—Ga—Se solar cell of the present invention can have the characteristics of high cell efficiency, high glass transition temperature, a prescribed average coefficient of thermal expansion, high glass strength, low glass density, meltability and formability during production of a sheet glass, and prevention of devitrification in good balance. A solar cell having high cell efficiency can be provided by using the glass substrate for a CIGS solar cell of the present invention.

The disclosures of the present application are related to the subject matter described in Japanese Patent Application No. 2011-016475 filed on Jan. 28, 2011, and the contents of those disclosures are incorporated herein by reference.

### BRIEF DESCRIPTION OF THE DRAWINGS

FIG. 1 is a cross-sectional view schematically showing an example of embodiments of a solar cell using the glass substrate for a CIGS solar cell of the present invention.

FIG. 2 shows (a) a solar cell prepared on a glass substrate for evaluation in Examples and (b) a cross-sectional view thereof.

FIG. 3 shows a CIGS solar cell for evaluaion on a glass substrate for evaluation, where eight pieces of the solar cell shown in FIG. 2 are arranged.

### MODE FOR CARRYING OUT THE INVENTION

### Glass Substrate for Cu—In—Ga—Se Solar Cell of the Present Invention

The glass substrate for a Cu—In—Ga—Se solar cell of the present invention will be explained below.

The glass substrate for a Cu—In—Ga—Se solar cell of the present invention is a glass substrate for a Cu—In—Ga—Se solar cell, containing, in terms of mol % on the basis of the following oxides:

from 60 to 75% of SiO₂;

from 1 to 7.5% of Al₂O₃;

from 0 to 1% of B₂O₃;

from 8.5 to 12.5% of MgO;

from 1 to 6.5% of CaO;

from 0 to 3% of SrO;

from 0 to 3% of BaO;

from 0 to 3% of ZrO₂;

from 0 to 3% of TiO₂;

from 1 to 8% of Na₂O; and

from 2 to 12% of K₂O,

wherein MgO+CaO+SrO+BaO is from 10 to 24%,

Na₂O+K₂O is from 5 to 15%,

MgO/Al₂O₃ is 1.3 or more,

(2Na₂O+K₂O+SrO+BaO)/(Al₂O₃+ZrO₂) is 3.3 or less,

Na₂O/K₂O is from 0.2 to 2.0

Al₂O₃≧−0.94MgO+11, and

CaO≧−0.48MgO+6.5,

wherein the glass substrate has a glass transition temperature of 640° C. or higher, an average coefficient of thermal expansion within a range of 50 to 350° C. of from 70×10⁻⁷ to 90×10⁻⁷/° C., a temperature (T₄) at which a viscosity reaches 10⁴ dPa·s of 1,230° C. or lower, a temperature (T₂) at which a viscosity reaches 10² dPa·s of 1,650° C. or lower, a relationship between the T₄ and a devitrification temperature (T_{L}) of T₄−T_{L}≧−30° C., and a density of 2.7 g/cm³ or less.

The Cu—In—Ga—Se will be described as “CIGS” hereinbelow.

The glass transition temperature (Tg) of the glass substrate for a CIGS solar cell of the present invention is 640° C. or higher, and is higher than a glass transition temperature of a soda lime glass. For the purpose of ensuring the formation of a CIGS layer at a high temperature, the glass transition temperature (Tg) is preferably 645° C. or higher, more preferably 650° C. or higher, and still more preferably 655° C. or higher. For the purpose that viscosity during melting is not excessively increased, the glass transition temperature is preferably 750° C. or lower, more preferably 720° C. or lower, and still more preferably 690° C. or lower.

An average coefficient of thermal expansion within the range of 50 to 350° C. of the glass substrate for a CIGS solar cell of the present invention is from 70×10⁻⁷ to 90×10⁻⁷/° C. When it is less than 70×10⁻⁷/° C. or exceeds 90×10⁻⁷1° C., the difference in thermal expansion to the CIGS layer is excessively large, and defects such as peeling are easy to occur. It is preferably 85×10⁻⁷/° C. or less.

In the glass substrate for a CIGS solar cell of the present invention, the relationship between a temperature (T₄) at which a viscosity reaches 10⁴ dPa·s and a devitrification temperature (T_{L}) is T₄−T_{L}≧−30° C. When T₄−T_{L} is lower than −30° C., devitrification is easy to occur during the formation of a sheet glass, and there is a concern that the formation of a glass sheet becomes difficult. T₄−T_{L} is preferably −20° C. or higher, more preferably −10° C. or higher, still more preferably 0° C. or higher, and especially preferably 10° C. or higher. The devitrification temperature used herein means a maximum temperature at which crystals are not precipitated on the glass surface and inside the glass when the glass is maintained at a specific temperature for 17 hours.

Considering formability of a glass sheet, that is, enhancement in flatness and enhancement in productivity, T₄ is 1,230° C. or lower. T₄ is preferably 1,220° C. or lower, and more preferably 1,210° C. or lower.

Considering meltability of a glass, that is, enhancement in homogeneity and enhancement in productivity, the glass substrate for a CIGS solar cell of the present invention has a temperature (T₂) at which a viscosity reaches 10² dPa·s of 1,650° C. or lower. T₂ is preferably 1,630° C. or lower, and more preferably 1,620° C. or lower.

In the glass substrate for a CIGS solar cell of the present invention, Young's modulus is preferably 75 GPa or more. When the Young's modulus is less than 75 GPa, strain amount under a constant stress is increased, warpage occurs in a production process, thereby causing problems, and there is a concern that the deposition cannot be normally performed. Furthermore, warpage of a product is increased, which is not preferred. The Young's modulus is more preferably 76 GPa or more, and still more preferably 77 GPa or more. Considering a glass composition range capable of easily producing a glass substrate in the case of producing the glass substrate by the ordinary method such as a float process or a fusion process, the Young's modulus is generally 90 GPa or less.

Specific elastic modulus (E/d) obtained by dividing Young's modulus (hereinafter referred to as “E”) by a density (hereinafter referred to as “d”) is preferably 28 GPa·cm³/g or more. When the specific elastic modulus is smaller than 28 GPa·cm³/g, the glass substrate sags by the weight itself during conveying by rollers or in the case of partially supporting, and the glass substrate may not be normally fluidized during the production process. The specific elastic modulus is more preferably 29 GPa·cm³/g or more, and still more preferably 30 GPa·cm³/g or more. Considering a glass composition range capable of easily producing a glass substrate in the case of producing the glass substrate by the ordinary method such as a float process or a fusion process, the specific elastic modulus is generally 37.5 GPa·cm³/g or less. To achieve the specific elastic modulus (E/d) of 28 GPa·cm³/g or more, the Young's modulus and the density should fall within the ranges specified in the present application.

The glass substrate for a CIGS solar cell of the present invention preferably has the density of 2.7 g/cm³ or less. When the density exceeds 2.7 g/cm³, the weight of a product is increased, which is not preferred. The density is more preferably 2.65 g/cm³ or less, and still more preferably 2.6 g/cm³ or less. Considering a glass composition range capable of easily producing a glass substrate in the case of producing the glass substrate by the ordinary method such as a float process or a fusion process, the density is generally 2.4 g/cm³ or more.

The glass substrate for a CIGS solar cell of the present invention preferably has a brittleness index of less than 7,000 m^{-1/2}. When the brittleness index is 7,000 m^{-1/2} or more, the glass substrate is easy to be broken in the production process of a solar cell, which is not preferred. The brittleness index is more preferably 6,900 m^{-1/2} or less, and still more preferably 6,800 m^{-1/2} or less.

In the present invention, the brittleness index of a glass substrate is obtained as “B” defined by the following formula (J. Sehgal, et al., J. Mat. Sci. Lett., 14, 167 (1995)).

c/a=0.0056B^{2/3}P^{1/6} (1)

Here, P is a pressing load of a Vickers indenter and a and c are a diagonal length of the Vickers indentation mark and a length of cracks formed from the four corners (total length of symmetrical two cracks including the mark of the indenter). The brittleness index B is calculated using the size of the Vickers indentation marks formed on various glass substrate surface and the formula (1).

The reasons why the glass substrate for a CIGS solar cell of the present invention is limited to the foregoing composition are as follows.

SiO₂: SiO₂ is a component for forming a network of glass, and when its content is less than 60 mol % (hereinafter referred to simply as “%”), there is a concern that the heat resistance and chemical durability of the glass substrate are lowered, and the average coefficient of thermal expansion within the rage of 50 to 350° C. increases. The content thereof is preferably 62% or more, more preferably 63% or more, and still more preferably 64% or more.

However, when it exceeds 75%, there is a concern that the viscosity at a high temperature of the glass increases, and a problem that the meltability is deteriorated is caused. The content thereof is preferably 73% or less, more preferably 70% or less, and still more preferably 69% or less.

Al₂O₃: Al₂O₃ increases the glass transition temperature, enhances the weather resistance (solarization), heat resistance and chemical durability, and increases a Young's modulus. When its content is less than 1%, there is a concern that the glass transition temperature is lowered. Also, there is a concern that the average coefficient of thermal expansion within the range of 50 to 350° C. increases. The content thereof is preferably 1.5% or more, more preferably 2% or more, and still more preferably 3% or more.

However, when it exceeds 7.5%, there is a concern that the viscosity at a high temperature of glass increases, and the meltability is deteriorated. Also, there is a concern that the devitrification temperature increases, and the formability is deteriorated. Also, there is a concern that the cell efficiency is lowered. The content thereof is preferably 7% or less.

B₂O₃: B₂O₃ may be contained in an amount of up to 1% for the purposes of enhancing the meltability, etc. When its content exceeds 1%, the glass transition temperature decreases, or the average coefficient of thermal expansion within the range of 50 to 350° C. becomes small, and thus is not preferable for a process for forming the CIGS layer. In addition, the devitrification temperature is increased to easily cause the devitrification, resulting in difficulty of forming the glass sheet. The content thereof is preferably 0.5% or less. It is more preferred that B₂O₃ is not substantially contained.

The expression “is not substantially contained” means that it is not contained except the case where it is contained as unavoidable impurities originated from raw materials or the like, that is, means that it is not intentionally incorporated.

MgO: MgO is contained because it has effects for decreasing the viscosity during melting of glass, and promoting melting. However, when its content is less than 8.5%, there is a concern that the viscosity at a high temperature of glass increases, and the meltability is deteriorated. Also, there is a concern that the cell efficiency is lowered. The content thereof is preferably 9% or more, more preferably 9.5% or more, and still more preferably 10% or more.

However, when it exceeds 12.5%, there is a concern that the average coefficient of thermal expansion within the range of 50 to 350° C. increases. Also, there is a concern that the devitrification temperature increases. The content thereof is preferably 12% or less.

CaO: CaO can be contained because it has effects for decreasing the viscosity during melting of glass, and promoting melting. The content thereof is preferably 1% or more, more preferably 1.5% or more, and still more preferably 2% or more. However, when its content exceeds 6.5%, there is a concern that the average coefficient of thermal expansion within the range of 50 to 350° C. of the glass substrate increases. In addition, there is a concern that sodium is hard to move in the glass substrate, and thus, the cell efficiency is lowered. The content thereof is preferably 6% or less.

SrO: SrO can be contained because it has effects for decreasing the viscosity during melting of glass, and promoting melting. However, when its content exceeds 3%, there is a concern that the cell efficiency is lowered, and the average coefficient of thermal expansion within the range of 50 to 350° C. of the glass substrate increases, the density of the glass substrate increases, and the later-described brittleness index of the glass substrate increases. The content thereof is preferably 2.5% or less, and more preferably 2% or less.

BaO: BaO can be contained because it has effects for decreasing the viscosity during melting of glass, and promoting melting. However, when its content exceeds 3%, there is a concern that the cell efficiency is lowered, and the average coefficient of thermal expansion within the range of 50 to 350° C. of the glass substrate increases, the density of the glass substrate increases, and the brittleness index of the glass substrate increases. In addition, there is a concern that the Young's modulus is decreased. The content thereof is preferably 2% or less, and more preferably 1.5% or less.

ZrO₂: ZrO₂ can be contained because it has effects for decreasing the viscosity during melting of glass, and promoting melting. However, when its content exceeds 3%, there is a concern that the cell efficiency is lowered, and devitrification temperature is increased to easily cause the devitrification, resulting in difficulty of forming the sheet glass. The content thereof is preferably 2.5% or less. In addition, the content thereof is preferably 0.5% or more, and more preferably 1% or more.

TiO₂: TiO₂ may be contained in an amount of up to 3% for the purposes of enhancing the melting properties, and the like. When its content exceeds 3%, there is a concern that the devitrification temperature is increased to easily cause the devitrification, resulting in difficulty of forming the glass sheet. The content thereof is preferably 2% or less and more preferably 1% or less.

MgO, CaO, SrO and BaO: MgO, CaO, SrO, and BaO are contained in an amount of 10% or more in total from the standpoints of decreasing the viscosity during melting of glass and promoting melting. However, when the total content exceeds 24%, there is a concern that the devitrification temperature increases and the formability is deteriorated. The total content is preferably 11% or more, more preferably 12% or more, and still more preferably 13% or more. Also, the total content is preferably 22% or less, more preferably 20% or less, and still more preferably 19% or less.

With regard to MgO, CaO, SrO and BaO, it is preferred that the value of the following formula (2) is 0.4 or more.

MgO/(MgO+CaO+SrO+BaO) (2)

When alkaline earth metals diffuse into a CIGS layer that is a p-type semiconductor of a photoelectric conversion layer, those act as a donor. Therefore, there is a concern that the cell efficiency is lowered. Furthermore, it is considered that the diffusion of the alkaline earth metals gives influence on the formation of a compound of Cu, In, Ga and Se when forming a CIGS layer in the production process of a solar cell, and as a result, it is considered that the diffusion gives influence on the growth of crystals. For example, it is considered that unreacted elements of Cu, In, Ga and Se remain, and prevent the preparation of CIGS crystals. As a result, there is a concern that the cell efficiency is lowered. On the other hand, the alkaline earth metals are essential for the purpose of improvement in meltability of a glass.

The present inventors have found that Mg is difficult to diffuse into a CIGS layer from a glass substrate, as compared with other alkaline earth metal elements. This is considered due to that because ionic radius of Mg is small as compared with that of other alkaline earth metal elements, MgO can relatively incorporate in a portion near the network structure of SiO₂ in a glass, covalent bond between Mg and O is increased, and Mg becomes difficult to diffuse. As a result, it is considered that by embedding the place where alkaline earth metal elements can be originally present in the glass with Mg, the place where alkaline earth metal elements other than Mg is decreased, and as a result, other alkaline earth elements becomes difficult to diffuse. In particular, when Ca becomes difficult to diffuse, the same effect as the effect when CaO is decreased is expected, Na becomes easy to diffuse as described above, and this is expected to lead to enhancement in cell efficiency. In the present invention, to reduce diffusion of alkaline earth metals into the CIGS layer, in addition to the range of MgO described above, the above formula (2) defining the proportion of MgO in alkaline earth metal oxides is preferably 0.4 or more, more preferably 0.5 or more, still more preferably 0.55 or more, and especially preferably 0.6 or more.

When the value of the above formula (2) exceeds 0.9, there is a case that meltability is deteriorated. The value of the formula (2) is preferably 0.9 or less, more preferably 0.85 or less, and still more preferably 0.8 or less.

Na₂O: Na₂O is a component which contributes to an enhancement of the cell efficiency of the CIGS solar cell and is an essential component. Also, Na₂O has effects for decreasing the viscosity at a melting temperature of glass and making it easy to perform melting, and therefore, it is contained in an amount of from 1 to 8%. Na is diffused into the CIGS layer constituted on the glass substrate and enhances the cell efficiency; however, when its content is less than 1%, there is a concern that the diffusion of Na into the CIGS layer on the glass substrate is insufficient, and the cell efficiency is also insufficient. The content is preferably 1.5% or more, and more preferably 2% or more.

When the content of Na₂O exceeds 8%, the average coefficient of thermal expansion within the range of 50 to 350° C. tends to become large, and the glass transition temperature tends to be lowered. In addition, the chemical durability is deteriorated. In addition, there is a concern that the Young's modulus is decreased. The content thereof is preferably 7.5% or less, and more preferably 7% or less.

K₂O: K₂O has the same effects as those in Na₂O, and therefore, it is contained in an amount of from 2 to 12%. However, when its content exceeds 12%, there is a concern that the cell efficiency is lowered, the glass transition temperature is lowered, and the average coefficient of thermal expansion within the range of 50 to 350° C. of the glass substrate becomes large. In addition, there is a concern that the Young's modulus is decreased. In the case where K₂O is contained, its content is preferably 2% or more, more preferably 3% or more, and still more preferably 3.5% or more. The content thereof is preferably 10% or less, more preferably 9% or less, and still more preferably 8.5% or less.

Na₂O and K₂O: For the purpose of sufficiently decreasing the viscosity at a melting temperature of glass and for the purpose of enhancing the cell efficiency of a CIGS solar cell, the total content of Na₂O and K₂O is from 5 to 15%. The total content is preferably 6% or more, and more preferably 7% or more. However, when the total content exceeds 15%, there is a concern that the glass transition temperature excessively decreases. The total content is preferably 13% or less, and more preferably 12.5% or less.

A ratio of Na₂O to K₂O, Na₂O/K₂O, is 0.2 or more. When the amount of Na₂O is excessively small as compared with the amount of K₂O, there is a concern that the diffusion of Na into the CIGS layer on the glass substrate is insufficient and the cell efficiency is insufficient. The ratio is preferably 0.4 or more, more preferably 0.5 or more, and still more preferably 0.6 or more. However, when the ratio exceeds 2.0, there is a concern that the glass transition temperature is excessively lowered. The ratio is preferably 1.7 or less, more preferably 1.5 or less, still more preferably 1.4 or less, and especially preferably 1.3 or less.

Na₂O, K₂O, MgO and CaO: Na₂O and K₂O are effective to enhance characteristics of the CIGS layer, CaO is a factor that inhibits the diffusion of Na, and MgO inhibits the diffusion of Ca. Therefore, for the purpose of enhancement in the cell efficiency, 2×Na₂O+K₂O+MgO—CaO is preferably from 16 to 30%. When the value is smaller than 16%, there is a concern that sufficient cell efficiency is not obtained, and when the value exceeds 30%, there is a concern that Tg is lowered. The value is more preferably 17% or more, still more preferably 17.5% or more, and especially preferably 18% or more. The value is more preferably 28% or less, still more preferably 26% or less, and especially preferably 24% or less.

Al₂O₃ and MgO: For the purpose of inhibiting the increase in devitrification temperature, a ratio of MgO/Al₂O₃ is 1.3 or more. When the ratio is less than 1.3, there is a concern that the devitrification temperature is increased. The ratio is preferably 1.4 or more, and more preferably 1.5 or more. Considering weather resistance and chemical durability, the ratio is preferably 5 or less, more preferably 4 or less, and still more preferably 3 or less.

Al₂O₃≧−0.94MgO+11 should be satisfied. The present inventors have found that, in this case, Tg can easily be controlled to 640° C. or higher in the present invention. This is considered to be due to that Al₂O₃ and MgO have the large effect for increasing Tg as compared with other elements. The coefficient 0.94 means that the effect for increasing Tg of MgO is slightly inferior to that of Al₂O₃. It is preferably Al₂O₃≧−0.94MgO+12, more preferably Al₂O₃≧−0.94MgO+13, Al₂O₃.0.94MgO+13.5, and especially preferably Al₂O₃≧−0.94MgO+14.

CaO and MgO: CaO≧−0.48MgO+6.5 should be satisfied. The present inventors have found that, in this case, T₄ can easily be controlled to 1,230° C. or lower in the present invention. This is considered to be due to that CaO and MgO has the large effect for decreasing T₄ while maintaining Tg, as compared with other elements. The coefficient 0.48 means that the contribution of MgO is about ½ of CaO. It is preferably CaO≧−0.48MgO+7, more preferably CaO≧−0.48MgO+7.5, and still more preferably CaO≧−0.48MgO+8.

Na₂O, K₂O, SrO, BaO, Al₂O₃ and ZrO₂: For the purpose of maintaining the glass transition temperature sufficiently high and for the purpose of enhancing weather resistance, the value of the following formula (3) is 3.3 or less.

(2Na₂O+K₂O+SrO+BaO)/(Al₂O₃+ZrO₂) (3)

The present inventors have found from the results of experiments and trials and errors that when the above each component satisfies the range of the present invention and the value obtained by the above formula is 3.3 or less, the cell efficiency becomes good while maintaining the glass transition temperature sufficiently high. The value is preferably 3 or less, and more preferably 2.8 or less.

When the value exceeds 3.3, there is a concern that the glass transition temperature is decreased, or weather resistance is deteriorated. When the value is too low, there is a tendency that the viscosity at a high temperature becomes high, and meltability and moldability are lowered. Therefore, the value is preferably 0.5 or more, and more preferably 1 or more.

The reason that Na₂O has the coefficient of 2 is that the effect of lowering Tg is higher than that of other components.

The glass substrate for a Cu—In—Ga—Se solar cell is preferably a glass substrate for a Cu—In—Ga—Se solar cell, containing, in terms of mol % on the basis of the following oxides:

from 62 to 73% of SiO₂;

from 1.5 to 7% of Al₂O₃;

from 0 to 1% of B₂O₃;

from 9 to 12.5% of MgO;

from 1.5 to 6.5% of CaO;

from 0 to 2.5% of SrO;

from 0 to 2% of BaO;

from 0.5 to 3% of ZrO₂;

from 0 to 3% of TiO₂;

from 1 to 7.5% of Na₂O; and

from 2 to 10% of K₂O,

wherein MgO+CaO+SrO+BaO is from 11 to 22%,

Na₂O+K₂O is from 6 to 13%,

MgO/Al₂O₃ is 1.4 or more,

(2Na₂O+K₂O+SrO+BaO)/(Al₂O₃+ZrO₂) is from 0.5 to 3,

Na₂O/K₂O is from 0.4 to 1.7

Al₂O₃≧−0.94MgO+12, and

CaCo≧−0.48MgO+7,

wherein the glass substrate has the glass transition temperature of 645° C. or higher, the average coefficient of thermal expansion within a range of 50 to 350° C. of from 70×10⁻⁷ to 85×10⁻⁷/° C., the temperature (T₄) at which a viscosity reaches 10⁴ dPa·s of 1,220° C. or lower, the temperature (T₂) at which a viscosity reaches 10² dPa·s of 1,630° C. or lower, the relationship between the T₄ and a devitrification temperature (T_{L}) of T₄−T_{L}≧−20° C., and the density of 2.65 g/cm³ or less.

Though the glass substrate for a CIGS solar cell of the present invention is essentially composed of the foregoing base composition, it may contain other components each in an amount of 1% or less and in an amount of 5% or less in total within the range where an object of the present invention is not impaired. For example, there may be the case where ZnO, Li₂O, WO₃, Nb₂O₅, V₂O₅, Bi₂O₃, MoO₃, TlO₂, P₂O₅, and the like may be contained for the purpose of improving the weather resistance, melting properties, devitrification, ultraviolet ray shielding, refractive index, and the like.

Also, for the purpose of improving the melting properties and fining property of glass, SO₃, F, Cl, and SnO₂ may be added into the base composition such that these materials are contained each in an amount of 1% or less and in an amount of 2% or less in total in the composition of the glass substrate.

For the purpose of enhancing the chemical durability of glass substrate, Y₂O₃ and La₂O₃ may be contained in an amount of 2% or less in total in the composition of the glass substrate.

For the purpose of adjusting the color tone of the glass substrate, colorants such as Fe₂O₃ may be contained in the glass substrate. A content of such colorants is preferably 1% or less in total.

Considering an environmental load, it is preferable that the glass substrate for a CIGS solar cell of the present invention does not substantially contain As₂O₃ and Sb₂O₃. Also, considering the stable achievement of float forming, it is preferable that the glass substrate does not substantially contain ZnO. However, the glass substrate for a CIGS solar cell of the present invention may be manufactured by forming by a fusion process without limitation to forming by the float process.

### <Manufacturing Method of Glass Substrate for CIGS Solar Cell of the Present Invention>

A manufacturing method of the glass substrate for a CIGS solar cell of the present invention will be described.

In the case of manufacturing the glass substrate for a CIGS solar cell of the present invention, similar to the case of manufacturing conventional glass substrates for a solar cell, a melting/fining step and a forming step are carried out. Since the glass substrate for a CIGS solar cell of the present invention is an alkali glass substrate containing an alkali metal oxide (Na₂O and K₂O), SO₃ can be effectively used as a refining agent, and a float process or a fusion process (down draw process) is suitable as the forming method.

In the manufacturing step of a glass substrate for a solar cell, it is preferable to adopt, as a method for forming a glass into a sheet form, a float process in which a glass substrate with a large area can be formed easily and stably with an increase in size of solar cells.

A preferred embodiment of the manufacturing method of the glass substrate for CIGS solar cell of the present invention will be described.

First of all, a molten glass obtained by melting raw materials is formed into a sheet form. For example, the raw materials are prepared so that the glass substrate to be obtained has a composition as mentioned above, and the raw materials are continuously thrown into a melting furnace, followed by heating at from 1,550 to 1,700° C. to obtain a molten glass. Then, this molten glass is formed into a glass sheet in a ribbon form by applying, for example, a float process.

Subsequently, the glass sheet in a ribbon form is taken out from the float forming furnace, followed by cooling to a room temperature state by cooling means, and cutting to obtain a glass substrate for a CIGS solar cell.

### <Use of Glass Substrate for CIGS Solar Cell of the Present Invention>

The glass substrate for a CIGS solar cell of the present invention is suitable as a glass substrate or cover glass of a CIGS solar cell. Particularly, the glass substrate of the present invention is suitable as a glass substrate for a CIGS solar cell manufactured by a selenization method.

In the case of applying the glass substrate for CIGS solar cell of the present invention to a glass substrate of a CIGS solar cell, a thickness of the glass substrate is preferably 3 mm or less, more preferably 2 mm or less, and still more preferably 1.5 mm or less. A method for imparting a CIGS layer to the glass substrate is not particularly limited.

By using the glass substrate for CIGS solar cell of the present invention, a heating temperature when forming the CIGS layer can be set to from 500 to 700° C., and preferably from 600 to 700° C.

In the case of using the glass substrate for CIGS solar cell of the present invention for only a glass substrate of a CIGS solar cell, a cover glass and the like are not particularly limited. Other examples of a composition of the cover glass include soda lime glass and the like.

In the case of using the glass substrate for a CIGS solar cell of the present invention as a cover glass of a CIGS solar cell, a thickness of the cover glass is preferably 3 mm or less, more preferably 2 mm or less, and still more preferably 1.5 mm or less. Also, a method for assembling the cover glass in a glass substrate including a CIGS layer is not particularly limited.

In the case of assembling upon heating using the glass substrate for a CIGS solar cell of the present invention, its heating temperature can be set to from 500 to 700° C., and preferably from 600 to 700° C.

When the glass substrate for a CIGS solar cell of the present invention is used for both a glass substrate and a cover glass of a CIGS solar cell, since the average coefficient of thermal expansion within the range of from 50 to 350° C. is equal, thermal deformation or the like does not occur during assembling the solar cell, and thus the case is preferred.

### <CIGS Solar Cell in the Present Invention>

The solar cell in the present invention is described below.

The solar cell in the present invention has a glass substrate, a cover glass, and a photoelectric conversion layer of Cu—In—Ga—Se provided between the glass substrate and the cover glass, and

at least the glass substrate of the glass substrate and the cover glass is the glass substrate for a Cu—In—Ga—Se solar cell of the present invention.

The solar cell of the present invention will be hereunder described in detail by reference to the accompanying drawings. It should not be construed that the present invention is limited to the accompanying drawings.

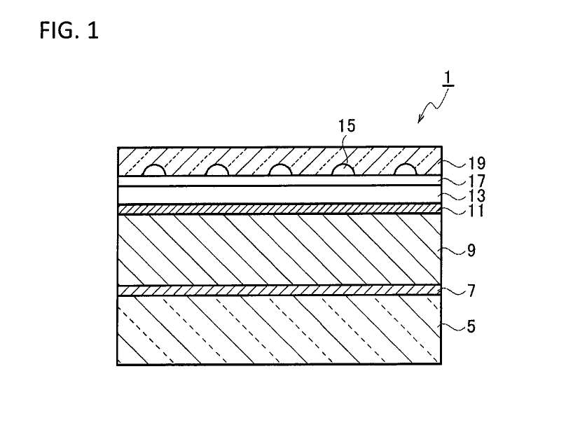

FIG. 1 is a cross-sectional view schematically showing an example of embodiments of the solar cell in the present invention.

In FIG. 1, a CIGS solar cell 1 in the present invention includes a glass substrate 5, a cover glass 19, and a CIGS layer 9 between the glass substrate 5 and the cover glass 19. The glass substrate 5 is preferably composed of the glass substrate for a CIGS solar cell of the present invention as described above. The solar cell 1 includes a back electrode layer of a molybdenum film that is a plus electrode 7 on the glass substrate 5, on which the CIGS layer 9 is provided. As the composition of the CIGS layer, Cu(In₁₋ₓGaₓ)Se₂ can be exemplified. x represents a composition ratio of In and Ga and satisfies a relation of 0<x<1.

On the CIGS layer 9, a CdS (cadmium sulfide), a ZnS (zinc sulfide) layer, a ZnO (zinc oxide) layer, a Zn(OH)₂ (zinc hydroxide) layer, or a mixed crystal layer thereof as a buffer layer 11 is provided. A transparent conductive film 13 of ZnO, ITO, Al-doped ZnO (AZO), or the like is provided through the buffer layer 11 and an extraction electrode such as an Al electrode (aluminum electrode) that is a minus electrode 15, and the like is further provided thereon. An antireflection film may be provided between these layers in a necessary place. In FIG. 1, an antireflection film 17 is provided between the transparent conductive film 13 and the minus electrode 15.

Also, the cover glass 19 may be provided on the minus electrode 15, and if necessary, a gap between the minus electrode and the cover glass is sealed with a resin or adhered with a transparent resin for adhesion. The glass substrate for a CIGS solar cell of the present invention may be used for the cover glass.

In the present invention, end parts of the CIGS layer or end parts of the solar cell may be sealed. Examples of a material for sealing include the same materials as those in the glass substrate for a CIGS solar cell of the present invention and the other glasses and resins.

It should not be construed that a thickness of each layer of the solar cell shown in the accompanying drawings is limited to that shown in the drawing.

The solar cell using the glass substrate for a CIGS solar cell of the present invention preferably has the cell efficiency of 12% or more, more preferably 12.5% or more, still more preferably 13% or more, and especially preferably 13.5% or more. The cell efficiency used herein means a cell efficiency obtained by the evaluation method of cell efficiency used in the examples described hereinafter.

### EXAMPLES

The present invention is described in more detail below with reference to the following Examples and Manufacturing Examples, but it should not be construed that the present invention is limited to these Examples and Manufacturing Examples.

Examples (Examples 1 to 35) of the glass substrate for a CIGS solar cell of the present invention and Comparative Examples (Examples 36 to 42) are described. The numerical values in the parentheses in Tables 1 to 6 are calculated values.

Raw materials of respective components were made up so as to have a composition shown in Tables 1 to 6, a sulfate was added to the raw materials in an amount of 0.1 parts by mass in terms of SO₃ per 100 parts by mass of the raw materials of the components for the glass substrate, followed by heating and melting at a temperature of 1,600° C. for 3 hours using a platinum crucible. In melting, a platinum stirrer was inserted, and stirring was performed for 1 hour, thereby homogenizing the glass. The molten glass was flown out and formed into a sheet form, followed by cooling. Thus, a glass sheet was obtained.

With respect to the glass sheet thus obtained, an average coefficient of thermal expansion within the range of 50 to 350° C. (unit: ×10⁻⁷/° C.), a glass transition temperature Tg (unit: ° C.), a temperature (T₄) (unit: ° C.) at which the viscosity reaches 10⁴ dPa·s, a temperature (T₂) (unit: ° C.) at which the viscosity reaches 10² dPa·s, a devitrification temperature (T_{L}) (unit: ° C.), a density (unit: g/cm³), a brittleness index (unit: m^{-1/2}), a Young's modulus (unit: GPa), cell efficiency (unit:%), a Ca diffusion amount and an Na diffusion amount were measured and shown in Tables 1 to 6. Measurement method of each property is shown below.

In the Examples, properties of the glass sheet are measured, but each property is the same between the glass sheet and the glass substrate. The glass substrate can be obtained by subjecting the glass sheet obtained to processing and polishing.

(1) Tg: Tg is a value as measured using TMA and was determined in conformity with JIS R3103-3 (2001).

(2) Average coefficient of thermal expansion within the range of from 50 to 350° C.: The average coefficient of thermal expansion was measured using a differential thermal expansion meter (TMA) and determined in conformity with JIS R3102 (1995).

(3) Viscosity: The viscosity was maesured using a rotary viscometer and a temperature T₂ (a reference temperature for meltability) at which the viscosity η thereof reached 10² dPa·s, a temperature T₄ (a reference temperature for formability) at which the viscosity η thereof of glass reached 10⁴ dPa·s.

(4) Devitrification temperature (T_{L}): 5 g of a glass block cut from the glass sheet were put on a platinum dish and maintained at a predetermined temperature for 17 hours in an electric furnace. After the temperature maintenance, a maximum value of temperature at which a crystal was not precipitated on and inside the glass block was defined as the devitrification temperature.

(5) Density: About 20 g of a glass block containing no bubbles was measured by Archimedes method.

(6) Brittleness index: The brittleness index B is calculated using each of aforementioned various glass sheets as a glass substrate and using a size of the Vickers indentation marks formed on the glass substrate surface and the formula (1).

(7) Young's modulus: With respect to a glass having a thickness of from 7 to 10 mm, the Young's modulus was measured with an ultrasonic pulse method.

(8) Cell efficiency: A solar cell for evaluation was fabricated as shown below using the obtained glass sheet as a substrate for the solar cell and evaluation of the cell efficiency was performed using the solar cell. Results are shown in Tables 1 to 6.

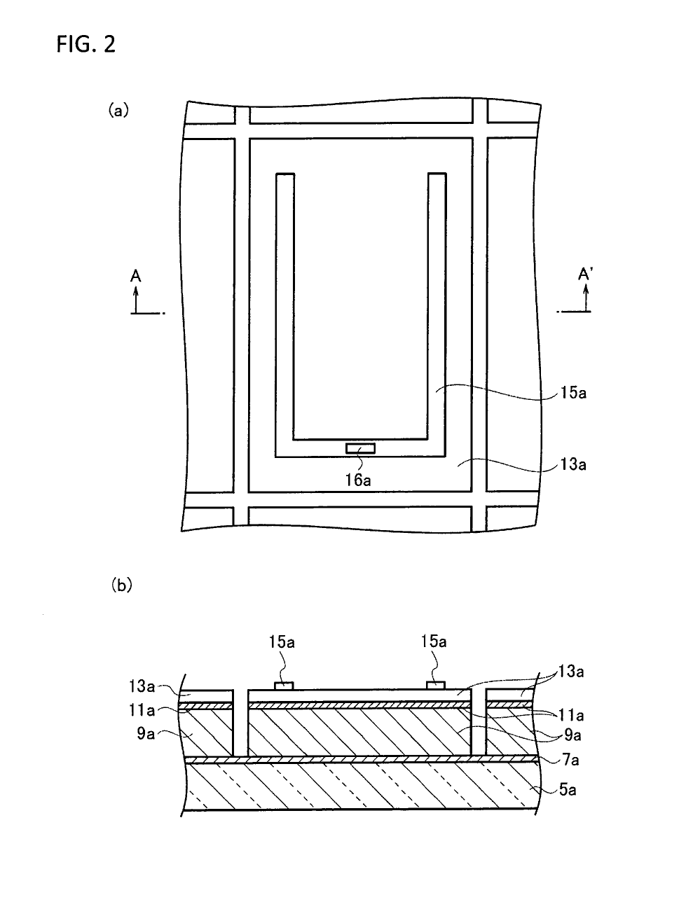

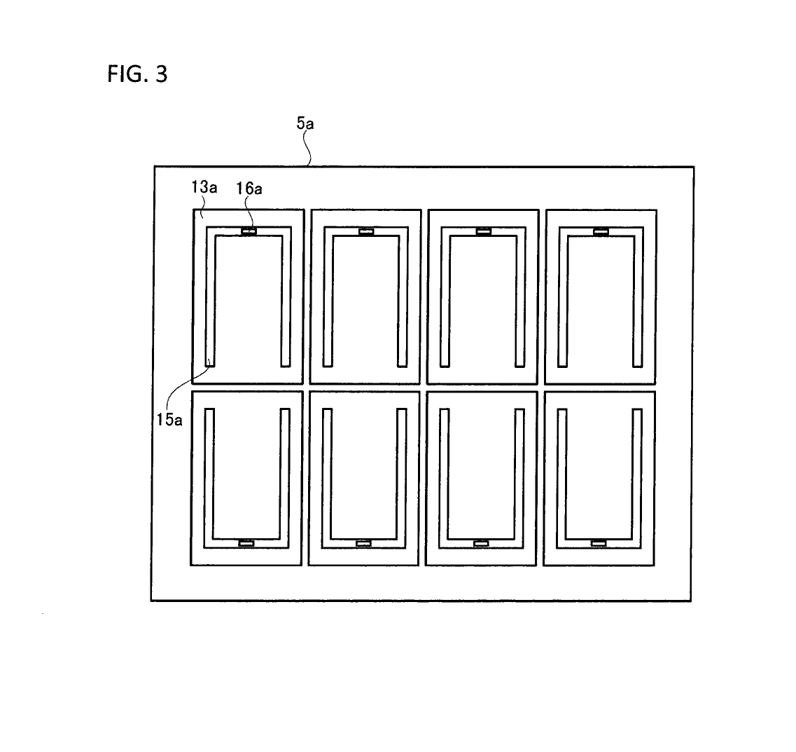

The fabrication of the solar cell for evaluation will be described below with reference to FIGS. 2 and 3 and reference numerals and signs thereof. The layer configuration of the solar cell for evaluation is almost the same as the layer configuration of the solar cell shown in FIG. 1 except that the cover glass 19 and antireflection film 17 of the solar cell in FIG. 1 are not included.

The obtained glass sheet was processed in a size of about 3 cm×3 cm and a thickness of 1.1 mm to obtain a glass substrate. A molybdenum film was formed as a plus electrode 7a on the glass substrate 5a by means of a sputtering apparatus. The deposition was carried out at room temperature and the molybdenum film having a thickness of 500 nm was obtained.

A CuGa alloy layer was deposited on the plus electrode 7a (molybdenum film) by means of a sputtering apparatus using a CuGa alloy target and subsequently an In layer was deposited using an In target, thereby forming a precursor film of In—CuGa. The deposition was carried out at room temperature. A thickness of each layer was adjusted so that a Cu/(Ga+In) ratio (atomic ratio) became 0.8 and a Ga/(Ga+In) ratio (atomic ratio) became 0.25 in the composition of the precursor film measured by fluorescent X-ray, thereby obtaining a precursor film having a thickness of 650 nm.

The precursor film was heat-treated in an argon/hydrogen selenide mixed atmosphere (hydrogen selenide is 5 vol % based on argon; the atmosphere is hereinafter referred to as “hydrogen selenide atmosphere”) or an argon/hydrogen sulfide mixed atmosphere (hydrogen sulfide is 5 vol % based on argon; the atmosphere is hereinafter referred to as “hydrogen sulfide atmosphere”) using RTA (Rapid Thermal Annealing) apparatus.

In condition 1, as a first stage, the precursor film was held at 250° C. for 30 minutes in the hydrogen selenide atmosphere to react Cu, In and Ga with Se. Subsequently, as a second stage, the precursor film was further held at 520° C. for 60 minutes to grow CIGS crystals. Thus, a CIGS layer 9a was obtained.

In condition 2, as a first stage, the precursor film was held at 250° C. for 30 minutes in the hydrogen selenide atmosphere to react Cu, In and Ga with Se. Subsequently, as a second stage, the atmosphere was substituted with the hydrogen sulfide atmosphere, and the precursor film was further held at 600° C. for 30 minutes, thereby sulfurizing CIGS crystals to substitute a part of Se of the CIGS crystals with S. Thus, the CIGS layer 9a having large band gap as compared with the condition 1 was obtained.

In both conditions, the thickness of the CIGS layer 9a obtained was 2 μm.

On the CIGS layer 9a, a CdS layer was deposited as a buffer layer 11a by the CBD (Chemical Bath Deposition) process. Specifically, first, cadmium sulfate having a concentration of 0.01M, thiourea having a concentration of 1.0M, ammonia having a concentration of 15M, and pure water were mixed in a beaker. Then, the CIGS layer was dipped in the mixed solution and the beaker with the layer was placed in a constant temperature bath whose water temperature had been set to 70° C. beforehand, thereby forming a CdS layer having a thickness of from 50 to 80 nm.

Furthermore, a transparent conductive film 13a was deposited on the CdS layer by a sputtering apparatus by the following method. First, a ZnO layer was deposited using a ZnO target and then an AZO layer was deposited using an AZO target (a ZnO target containing Al₂O₃ in an amount of 1.5 wt %). The deposition of each layer was carried out at room temperature and a two-layered transparent conductive film 13a having a thickness of 480 nm was obtained.

An aluminum film having a thickness of 1 μm was deposited as a U-shaped minus electrode 15a on the AZO layer of the transparent conductive film 13a by EB deposition method (electrode length of the U-shape: (8 mm in length and 4 mm in width), electrode width: 0.5 mm).

Finally, the resultant was shaven from the transparent conductive film 13a side to the point of the CIGS layer 9a by means of a mechanical scribe, thereby forming a cell as shown in FIG. 2. FIG. 2(a) is a drawing in which one solar cell is viewed from the top face and FIG. 2(b) is a cross-sectional view at A-A′ in FIG. 2(a). One cell has a width of 0.6 cm and a length of 1 cm, and an area exclusive of the minus electrode 15a was 0.5 cm². As shown in FIG. 3, eight cells in total were obtained on one glass substrate 5a.

The CIGS solar cell for evaluation (the above glass substrate 5a for evaluation on which the eight cells were fabricated) was mounted on a solar simulator (YSS-T80A manufactured by Yamashita Denso Corporation); and a plus terminal (not shown) for the plus electrode 7a previously coated with an InGa solvent and a minus terminal 16a for the lower end of the U shape of the minus electrode 15a were respectively connected to a voltage generator. The temperature within the solar simulator was controlled constant at 25° C. by a temperature regulator. The solar cell was irradiated with a pseudo sun light and, after 10 seconds, the voltage was changed from −1V to +1V at intervals of 0.015 V, thereby measuring a current value of each of the eight cells.

A cell efficiency was calculated from the current and voltage characteristics during the irradiation according to the following formula (4). Among the eight cells, a value of the cell exhibiting the best efficiency is shown as a value of cell efficiency of each glass substrate in Tables 1 to 6. The illuminance of the light source used in the test was 0.1W/cm².

Cell efficiency [%]=Voc[V]×Jsc[A/cm²]×FF(dimensionless)×100/(Illuminance of light source used for the test) [W/cm²] (4)

The cell efficiency is determined by multiplication of an open circuit voltage (Voc), a short-circuit current density (Jsc), and a fill factor (FF).

Here, the open circuit voltage (Voc) is an output when the terminal is opend; the short-circuit current (Isc) is a current when short-circuit is occurred. The short-circuit current density (Jsc) is one obtained by dividing Isc by an area of the cell exclusive of the minus electrode.

Also, a point at which a maximum output is given is called a maximum output point and a voltage at that point is called a maximum voltage value (Vmax) and a current at that point is called a maximum current value (Imax). A value obtained by dividing the product of the maximum voltage value (Vmax) and the maximum current value (Imax) by the product of the open circuit voltage (Voc) and the short-circuit current (Isc) is determined as the fill factor (FF). Using the above value, the cell efficiency was determined.

(9) Ca diffusion amount: For the purpose of observing the effect of the glass substrate by diffusion of alkaline earth elements, just after completion of the first stage of RTA treatment for the preparation of a solar cell in the evaluation of cell efficiency of the above (8), the Ca diffusion amount was measured as a diffusion amount of alkaline earth elements. The measurement method is as follows.

After completion of the first stage of heating by the above RTA apparatus, the sample was subjected to secondary ion mass spectrometry (SIMS, product name: ADEPT1010, manufactured by ULVAC-PHI, Inc. was used) to measure integral intensity of ⁴⁰Ca in a molybdenum film, and the value was defined as an index of the Ca diffusion amount.

The measurement of integral intensity by SIMS was that the glass substrate of Example 10 was measured as the reference every measurement date, and the numerical value on the basis of the value was defined as the Ca diffusion amount.

(10) Na diffusion amount: For the purpose of observing the effect of the glass substrate by diffusion of alkali elements, just after completion of the first stage of RTA treatment for the preparation of a solar cell in the evaluation of cell efficiency of the above (8), the Na diffusion amount was measured as a diffusion amount of alkali elements. The measurement method was that the sample was subjected to the secondary ion mass spectrometry (SIMS) in the same method as the measurement method of the Ca diffusion amount of the above (9) to measure integral intensity of ²³Na in a molybdenum film, and the value was defined as an index of the Na diffusion amount.

The measurement of integral intensity by SIMS was that the glass substrate of Example 10 was measured as the reference every measurement date, and the numerical value on the basis of the value was defined as the Na diffusion amount.

The residual amount of SO₃ in the glass was from 100 to 500 ppm.

TABLE 1

| Composition (mol %) | Ex. 1 | Ex. 2 | Ex. 3 | Ex. 4 | Ex. 5 | Ex. 6 | Ex. 7 |
|---|---|---|---|---|---|---|---|
| SiO₂ | 64.5 | 66.0 | 69.5 | 68.5 | 66.0 | 66.0 | 65.75 |
| Al₂O₃ | 6.5 | 5.0 | 2.0 | 3.5 | 6.0 | 6.0 | 6.5 |
| B₂O₃ | 0 | 0 | 0 | 0 | 0 | 0 | 0 |
| MgO | 12.0 | 11.5 | 12.0 | 12.0 | 11.0 | 10.0 | 10.25 |
| CaO | 2.5 | 3.5 | 3.5 | 3.5 | 3.5 | 3.5 | 5.25 |
| SrO | 1.0 | 1.0 | 1.5 | 0 | 0.5 | 0 | 0 |
| BaO | 0 | 0.5 | 1.0 | 0 | 0.5 | 0 | 0 |
| ZrO₂ | 2.0 | 2.0 | 2.0 | 2.0 | 1.5 | 1.5 | 1.75 |
| TiO₂ | 0 | 0 | 0 | 0 | 0 | 2.0 | 0 |
| Na₂O | 4.5 | 5.0 | 1.5 | 3.5 | 5.0 | 5.0 | 6.25 |
| K₂O | 7.0 | 5.5 | 7.0 | 7.0 | 6.0 | 6.0 | 4.25 |
| MgO + CaO + SrO + BaO | 15.5 | 16.5 | 18.0 | 15.5 | 15.5 | 13.5 | 15.5 |
| Na₂O + K₂O | 11.5 | 10.5 | 8.5 | 10.5 | 11.0 | 11.0 | 10.5 |
| MgO/Al₂O₃ | 1.85 | 2.30 | 6.00 | 3.43 | 1.83 | 1.67 | 1.58 |
| (2Na₂O + K₂O + SrO + BaO)/ | 2.00 | 2.43 | 3.13 | 2.55 | 2.27 | 2.13 | 2.03 |
| (Al₂O₃ + ZrO₂) | | | | | | | |
| Na₂O/K₂O | 0.64 | 0.91 | 0.21 | 0.50 | 0.83 | 0.83 | 1.47 |
| 2Na₂O + K₂O + MgO—CaO | 25.50 | 23.50 | 18.50 | 22.50 | 23.50 | 22.50 | 21.75 |
| MgO/(MgO + CaO + SrO + BaO) | 0.77 | 0.70 | 0.67 | 0.77 | 0.71 | 0.74 | 0.66 |
| -0.94MgO + 11 | −0.28 | 0.19 | −0.28 | −0.28 | 0.66 | 1.60 | 1.37 |
| -0.94MgO + 12 | 0.72 | 1.19 | 0.72 | 0.72 | 1.66 | 2.60 | 2.37 |
| -0.48MgO + 6.5 | 0.74 | 0.98 | 0.74 | 0.74 | 1.22 | 1.70 | 1.58 |
| -0.48MgO + 7 | 1.24 | 1.48 | 1.24 | 1.24 | 1.72 | 2.20 | 2.08 |
| Density (g/cm³) | (2.54) | (2.56) | (2.57) | 2.51 | 2.54 | 2.52 | 2.54 |
| Average coefficient of thermal | (79) | (76) | (72) | 76 | 79 | 77 | 78 |
| expansion (×10⁻⁷/° C.) | | | | | | | |
| Tg (° C.) | (662) | (653) | (661) | 660 | 650 | 651 | 652 |
| T₄ (° C.) | (1226) | (1197) | (1208) | (1217) | (1213) | 1213 | (1201) |
| T₂ (° C.) | (1648) | (1616) | (1627) | (1648) | (1641) | 1626 | (1625) |
| Devitrification temperature T_{L} (° C.) | 1225 | 1175 | 1200 | 1200 | 1200 | 1200 | 1220 |
| T₄ − T_{L} (° C.) | 1 | 22 | 8 | 17 | 13 | 13 | −19 |
| Brittleness index (m^{-1/2}) | (5950) | (6150) | (6200) | 5850 | 6050 | 5900 | 5800 |
| Young's modulus (GPa) | (76.4) | (77.6) | (76.5) | 74.9 | (76.1) | (77.5) | (78.2) |
| Specific elastic modulus | (30.1) | (30.3) | (29.8) | (29.8) | (30.0) | (30.8) | (30.8) |
| (GPa · cm³/g) | | | | | | | |
| Cell efficiency (%) (Condition 1) | | | | 12.4 | | | |
| Voc (V) (Condition 1) | | | | 0.55 | | | |
| Jsc (mA/cm²) (Condition 1) | | | | 39.9 | | | |
| FF (Condition 1) | | | | 0.56 | | | |
| Cell efficiency (%) (Condition 2) | | | | 13.5 | 13.7 | 15.2 | 14.9 |
| Voc (V) (Condition 2) | | | | 0.61 | 0.64 | 0.64 | 0.64 |
| Jsc (mA/cm²) (Condition 2) | | | | 34.9 | 31.0 | 33.5 | 32.5 |
| FF (Condition 2) | | | | 0.63 | 0.69 | 0.71 | 0.72 |
| Ca diffusion amount | | | | 306 | | | |
| Na diffusion amount | | | | 7.8 | | | |

TABLE 2

| Composition (mol %) | Ex. 8 | Ex. 9 | Ex. 10 | Ex. 11 | Ex. 12 | Ex. 13 |
|---|---|---|---|---|---|---|
| SiO₂ | 66.0 | 65.25 | 65.5 | 66.0 | 66.25 | 66.5 |
| Al₂O₃ | 6.25 | 6.25 | 6.0 | 5.5 | 5.5 | 5.0 |
| B₂O₃ | 0 | 0 | 0 | 0 | 0 | 0 |
| MgO | 10.0 | 10.0 | 11.0 | 10.25 | 10.5 | 12.0 |
| CaO | 5.5 | 5.5 | 5.0 | 5.5 | 5.5 | 5.0 |
| SrO | 0 | 0.75 | 0.5 | 0.75 | 0.75 | 0 |
| BaO | 0 | 0.5 | 0.25 | 0.25 | 1.0 | 0 |
| ZrO₂ | 1.75 | 1.75 | 1.75 | 1.75 | 1.5 | 1.5 |
| TiO₂ | 0 | 0 | 0 | 0 | 0 | 0 |
| Na₂O | 6.0 | 5.0 | 5.0 | 4.5 | 4.0 | 4.0 |
| K₂O | 4.5 | 5.0 | 5.0 | 5.5 | 5.0 | 6.0 |
| MgO + CaO + SrO + BaO | 15.5 | 16.8 | 16.8 | 16.8 | 17.8 | 17.0 |
| Na₂O + K₂O | 10.5 | 10.0 | 10.0 | 10.0 | 9.0 | 10.0 |
| MgO/Al₂O₃ | 1.60 | 1.60 | 1.83 | 1.86 | 1.91 | 2.40 |
| (2Na₂O + K₂O + SrO + BaO)/ | 2.06 | 2.03 | 2.03 | 2.14 | 2.11 | 2.15 |
| (Al₂O₃ + ZrO₂) | | | | | | |
| Na₂O/K₂O | 1.33 | 1.00 | 1.00 | 0.82 | 0.80 | 0.67 |
| 2Na₂O + K₂O + MgO—CaO | 21.00 | 19.50 | 21.00 | 19.25 | 18.00 | 21.00 |
| MgO/(MgO + CaO + SrO + BaO) | 0.65 | 0.60 | 0.66 | 0.61 | 0.59 | 0.71 |
| -0.94MgO + 11 | 1.60 | 1.60 | 0.66 | 1.37 | 1.13 | −0.28 |
| -0.94MgO + 12 | 2.60 | 2.60 | 1.66 | 2.37 | 2.13 | 0.72 |
| -0.48MgO + 6.5 | 1.70 | 1.70 | 1.22 | 1.58 | 1.46 | 0.74 |
| -0.48MgO + 7 | 2.20 | 2.20 | 1.72 | 2.08 | 1.96 | 1.24 |
| Density (g/cm³) | 2.54 | 2.57 | 2.55 | 2.56 | 2.58 | 2.52 |
| Average coefficient of thermal | 79 | 77 | 76 | 75 | 75.0 | 75.0 |
| expansion (×10⁻⁷/° C.) | | | | | | |
| Tg (° C.) | 650 | 653 | 657 | 652 | 655 | 655 |
| T₄ (° C.) | (1200) | 1200 | 1202 | 1207 | 1216 | (1201) |
| T₂ (° C.) | (1623) | 1597 | 1596 | 1612 | 1625 | (1622) |
| Devitrification temperature T_{L} (° C.) | 1220 | 1230 | 1215 | 1215 | 1215 | 1230 |
| T₄ − T_{L} (° C.) | −20 | −20 | −13 | −8 | 1 | −29 |
| Brittleness index (m^{-1/2}) | 6150 | 6200 | 6100 | 5900 | 6150 | 6050 |
| Young's modulus (GPa) | (77.9) | (78.0) | 78.4 | (77.6) | 77.3 | (77.5) |
| Specific elastic modulus | (30.7) | (30.4) | 31.2 | (30.3) | (30.8) | (30.8) |
| (GPa · cm³/g) | | | | | | |
| Cell efficiency (%) (Condition 1) | | | 13.9 | | 14.9 | |
| Voc (V) (Condition 1) | | | 0.55 | | 0.55 | |
| Jsc (mA/cm²) (Condition 1) | | | 40.1 | | 40.4 | |
| FF (Condition 1) | | | 0.63 | | 0.67 | |
| Cell efficiency (%) (Condition 2) | 12.1 | 15.7 | 14.3 | 15.9 | 14.1 | 15.2 |
| Voc (V) (Condition 2) | 0.63 | 0.64 | 0.64 | 0.64 | 0.62 | 0.62 |
| Jsc (mA/cm²) (Condition 2) | 31.2 | 34.9 | 31.6 | 35.5 | 33.3 | 34.7 |
| FF (Condition 2) | 0.62 | 0.70 | 071 | 0.70 | 0.68 | 0.71 |
| Ca diffusion amount | | | 311 | 235 | — | |
| Na diffusion amount | | | 8.9 | 10.3 | 6.9 | |

TABLE 3

| Composition (mol %) | Ex. 14 | Ex. 15 | Ex. 16 | Ex. 17 | Ex. 18 | Ex. 19 | Ex. 20 |
|---|---|---|---|---|---|---|---|
| SiO₂ | 66.25 | 66.5 | 64.75 | 66.5 | 65.5 | 65.5 | 65.5 |
| Al₂O₃ | 6.75 | 7.0 | 6.5 | 6.25 | 6.0 | 5.5 | 6.0 |
| B₂O₃ | 0 | 0 | 0 | 0 | 0 | 0 | 0 |
| MgO | 11.0 | 11.0 | 11.0 | 11.0 | 11.0 | 11.25 | 11.0 |
| CaO | 5.5 | 5.75 | 5.0 | 4.25 | 5.0 | 5.25 | 4.75 |
| SrO | 1.0 | 0.25 | 1.0 | 1.0 | 0.62 | 0.62 | 0.62 |
| BaO | 1.25 | 1.5 | 0 | 0 | 0.13 | 0.13 | 0.13 |
| ZrO₂ | 0.25 | 0 | 2.0 | 1.75 | 1.75 | 1.75 | 1.75 |
| TiO₂ | 0 | 0 | 0 | 0 | 0 | 0 | 0 |
| Na₂O | 4.0 | 4.25 | 4.5 | 4.75 | 3.0 | 3.0 | 3.25 |
| K₂O | 4.0 | 3.75 | 5.25 | 4.50 | 7.0 | 7.0 | 7.0 |
| MgO + CaO + SrO + BaO | 18.8 | 18.5 | 17.0 | 16.3 | 16.8 | 17.3 | 16.5 |
| Na₂O + K₂O | 8.0 | 8.0 | 9.8 | 9.3 | 10.0 | 10.0 | 10.3 |
| MgO/Al₂O₃ | 1.63 | 1.57 | 1.69 | 1.76 | 1.83 | 2.05 | 1.83 |
| (2Na₂O + K₂O + SrO + BaO)/ | 2.04 | 2.00 | 1.79 | 1.88 | 1.77 | 1.90 | 1.84 |
| (Al₂O₃ + ZrO₂) | | | | | | | |
| Na₂O/K₂O | 1.00 | 1.13 | 0.86 | 1.06 | 0.43 | 0.43 | 0.46 |
| 2Na₂O + K₂O + MgO—CaO | 17.50 | 17.50 | 20.25 | 20.75 | 19.00 | 19.00 | 19.75 |
| MgO/(MgO + CaO + SrO + BaO) | 0.59 | 0.59 | 0.65 | 0.68 | 0.66 | 0.65 | 0.67 |
| -0.94MgO + 11 | 0.66 | 0.66 | 0.66 | 0.66 | 0/66 | 0.43 | 0.66 |
| -0.94MgO + 12 | 1.66 | 1.66 | 1.66 | 1.66 | 1.66 | 1.43 | 1.66 |
| -0.48MgO + 6.5 | 1.22 | 1.22 | 1.22 | 1.22 | 1.22 | 1.10 | 1.22 |
| -0.48MgO + 7 | 1.72 | 1.72 | 1.72 | 1.72 | 1.72 | 1.60 | 1.72 |
| Density (g/cm³) | (2.55) | (2.54) | 2.57 | 2.55 | 2.55 | (2.54) | 2.55 |
| Average coefficient of thermal | 73 | 72 | 76 | 73 | 78 | (75) | 78 |
| expansion (×10⁻⁷/° C.) | | | | | | | |
| Tg (° C.) | 658 | 659 | 668 | 668 | 674 | (679) | 670 |
| T₄ (° C.) | 1215 | (1208) | 1212 | 1226 | 1227 | (1230) | (1219) |
| T₂ (° C.) | 1630 | (1631) | 1615 | 1635 | 1635 | (1650) | (1636) |
| Devitrification temperature T_{L} (° C.) | 1235 | 1238 | 1220 | 1240 | 1226 | 1246 | (1220) |
| T₄ − T_{L} (° C.) | −20 | −30 | −8 | −14 | 1 | −16 | >−1 |
| Brittleness index (m^{-1/2}) | 5900 | (6050) | (5950) | (5850) | (5900) | (5950) | 6050 |
| Young's modulus (GPa) | (78.2) | (77.8) | (78.9) | (78.6) | (76.9) | (76.7) | (76.7) |
| Specific elastic modulus | (30.7) | (30.6) | (30.7) | (30.8) | (30.2) | (30.2) | (30.1) |
| (GPa · cm³/g) | | | | | | | |
| Cell efficiency (%) (Condition 1) | | | | | | | |
| Voc (V) (Condition 1) | | | | | | | |
| Jsc (mA/cm²) (Condition 1) | | | | | | | |
| FF (Condition 1) | | | | | | | |
| Cell efficiency (%) (Condition 2) | 15.0 | 14.9 | | | | | 13.6 |
| Voc (V) (Condition 2) | 0.62 | 0.63 | | | | | 0.62 |
| Jsc (mA/cm²) (Condition 2) | 34.5 | 34.5 | | | | | 34.1 |
| FF (Condition 2) | 0.71 | 0.69 | | | | | 0.64 |
| Ca diffusion amount | | | | | | | 268 |
| Na diffusion amount | | | | | | | 5.4 |

TABLE 4

| Composition (mol %) | Ex. 21 | Ex. 22 | Ex. 23 | Ex. 24 | Ex. 25 | Ex. 26 | Ex. 27 |
|---|---|---|---|---|---|---|---|
| SiO₂ | 65.0 | 66.5 | 65.5 | 65.5 | 65.5 | 65.5 | 65.5 |
| Al₂O₃ | 6.35 | 4.75 | 6.0 | 5.5 | 5.5 | 6.0 | 6.5 |
| B₂O₃ | 0 | 0 | 0 | 0 | 0 | 0 | 0 |
| MgO | 11.0 | 11.75 | 10.5 | 10.5 | 11.0 | 11.0 | 11.0 |
| CaO | 4.8 | 4.5 | 4.5 | 4.0 | 5.0 | 5.0 | 5.25 |
| SrO | 0.75 | 0 | 1.0 | 0 | 0 | 0.5 | 0.5 |
| BaO | 0.1 | 0 | 0 | 0 | 0 | 0.25 | 0.5 |
| ZrO₂ | 2.0 | 1.75 | 1.5 | 1.5 | 1.0 | 0.25 | 0 |
| TiO₂ | | | 1.0 | 3.0 | 2.5 | 2.5 | 2.25 |
| Na₂O | 4.5 | 4.0 | 5.0 | 5.0 | 5.0 | 4.5 | 4.5 |
| K₂O | 5.5 | 6.75 | 5.0 | 5.0 | 4.5 | 4.5 | 4.0 |
| MgO + CaO + SrO + BaO | 16.7 | 16.3 | 16.0 | 14.5 | 16.0 | 16.8 | 17.3 |
| Na₂O + K₂O | 10.0 | 10.8 | 10.0 | 10.0 | 9.5 | 9.0 | 8.5 |
| MgO/Al₂O₃ | 1.73 | 2.47 | 1.75 | 1.91 | 2.00 | 1.83 | 1.69 |
| (2Na₂O + K₂O + SrO + BaO)/ | 1.84 | 2.27 | 2.13 | 2.14 | 2.23 | 2.28 | 2.15 |
| (Al₂O₃ + ZrO₂) | | | | | | | |
| Na₂O/K₂O | 0.82 | 0.59 | 1.00 | 1.00 | 1.11 | 1.00 | 1.13 |
| 2Na₂O + K₂O + MgO—CaO | 20.70 | 22.00 | 21.00 | 21.50 | 20.50 | 19.50 | 18.75 |
| MgO/(MgO + CaO + SrO + BaO) | 0.66 | 0.72 | 0.66 | 0.72 | 0.69 | 0.66 | 0.64 |
| -0.94MgO + 11 | 0.66 | −0.04 | 1.13 | 1.13 | 0.66 | 0.66 | 0.66 |
| -0.94MgO + 12 | 1.66 | 0.96 | 2.13 | 2.13 | 1.66 | 1.66 | 1.66 |
| -0.48MgO + 6.5 | 1.22 | 0.86 | 1.46 | 1.46 | 1.22 | 1.22 | 1.22 |
| -0.48MgO + 7 | 1.72 | 1.36 | 1.96 | 1.96 | 1.72 | 1.72 | 1.72 |
| Density (g/cm³) | 2.57 | (2.52) | (2.56) | (2.55) | (2.54) | (2.54) | (2.55) |
| Average coefficient of thermal | 77 | (77) | 76 | 76 | 75 | 73 | 71 |
| expansion (×10⁻⁷/° C.) | | | | | | | |
| Tg (° C.) | 665 | (660) | 654 | 652 | 650 | 652 | 659 |
| T₄ (° C.) | 1206 | (1202) | 1207 | 1200 | (1193) | 1186 | (1204) |
| T₂ (° C.) | 1606 | (1624) | 1619 | 1620 | (1601) | 1608 | (1617) |
| Devitrification temperature T_{L} (° C.) | 1220 | 1215 | 1214 | 1224 | 1220 | 1220 | 1229 |
| T₄ − T_{L} (° C.) | −14 | −13 | −7 | −24 | −27 | −22 | −25 |
| Brittleness index (m^{-1/2}) | (5950) | (6000) | 6150 | 5650 | (5700) | (5650) | 5500 |
| Young's modulus (GPa) | (78.4) | (76.5) | (79.3) | (79.6) | (79.8) | (79.2) | (79.4) |
| Specific elastic modulus | (30.5) | (30.4) | (31.0) | (31.2) | (31.4) | (31.2) | (31.1) |
| (GPa · cm³/g) | | | | | | | |
| Cell efficiency (%) (Condition 1) | | | | | | | |
| Voc (V) (Condition 1) | | | | | | | |
| Jsc (mA/cm²) (Condition 1) | | | | | | | |
| FF (Condition 1) | | | | | | | |
| Cell efficiency (%) (Condition 2) | | | 14.5 | 14.6 | | | 14.8 |
| Voc (V) (Condition 2) | | | 0.63 | 0.63 | | | 0.63 |
| Jsc (mA/cm²) (Condition 2) | | | 35.9 | 34.9 | | | 33.9 |
| FF (Condition 2) | | | 0.64 | 0.67 | | | 0.69 |
| Ca diffusion amount | | | | 319 | | | 249 |
| Na diffusion amount | | | | 10.4 | | | 7.4 |

TABLE 5

| Composition (mol %) | Ex. 28 | Ex. 29 | Ex. 30 | Ex. 31 | Ex. 32 | Ex. 33 | Ex. 34 | Ex. 35 |
|---|---|---|---|---|---|---|---|---|
| SiO₂ | 69.0 | 68.5 | 64.5 | 65.0 | 65.5 | 65.75 | 65.5 | 66.25 |
| Al₂O₃ | 3.25 | 3.5 | 6.0 | 6.0 | 5.75 | 5.5 | 6.0 | 5.5 |
| B₂O₃ | 0 | 0 | 0 | 0 | 0 | 0 | 1 | 1 |
| MgO | 11.0 | 12.0 | 11.5 | 11.0 | 11.0 | 10.0 | 10.75 | 10.5 |
| CaO | 4.0 | 3.5 | 2.5 | 2.0 | 4.0 | 4.5 | 5.0 | 5.5 |
| SrO | 2.0 | 0.5 | 2.0 | 2.0 | 0.5 | 0.5 | 0.5 | 0.75 |
| BaO | 0 | 0 | 0 | 1.25 | 0 | 0 | 0 | 0.5 |
| ZrO₂ | 1.5 | 2.0 | 2.0 | 1.75 | 1.75 | 1.75 | 1.75 | 1.5 |
| TiO₂ | 0 | 0 | 0 | 0 | 0 | 0 | 0 | 0 |
| Na₂O | 2.75 | 4.0 | 4.5 | 3.75 | 3.0 | 3.5 | 5.0 | 4.0 |
| K₂O | 6.5 | 6.0 | 7.0 | 7.25 | 8.5 | 8.5 | 5.0 | 5.0 |
| MgO + CaO + SrO + BaO | 17.0 | 16.0 | 16.0 | 16.3 | 15.5 | 15.0 | 16.3 | 17.3 |
| Na₂O + K₂O | 9.3 | 10.0 | 11.5 | 11.0 | 11.5 | 12.0 | 10.0 | 9.0 |
| MgO/Al₂O₃ | 3.38 | 3.43 | 1.92 | 1.83 | 1.91 | 1.82 | 1.79 | 1.91 |
| (2Na₂O + K₂O + SrO + BaO)/ | 2.95 | 2.64 | 2.25 | 2.32 | 2.00 | 2.21 | 2.00 | 2.04 |
| (Al₂O₃ + ZrO₂) | | | | | | | | |
| Na₂O/K₂O | 0.42 | 0.67 | 0.64 | 0.52 | 0.35 | 0.41 | 1.00 | 0.80 |
| 2Na₂O + K₂O + MgO—CaO | 19.00 | 22.50 | 25.00 | 23.75 | 21.50 | 21.00 | 20.75 | 18.00 |
| MgO/(MgO + CaO + SrO + BaO) | 0.65 | 0.75 | 0.72 | 0.68 | 0.71 | 0.67 | 0.66 | 0.61 |
| -0.94MgO + 11 | 0.66 | −0.28 | 0.19 | 0.66 | 0.66 | 1.60 | 0.90 | 1.13 |
| -0.94MgO + 12 | 1.66 | 0.72 | 1.19 | 1.66 | 1.66 | 2.60 | 1.90 | 2.13 |
| -0.48MgO + 6.5 | 1.22 | 0.74 | 0.98 | 1.22 | 1.22 | 1.70 | 1.34 | 1.46 |
| -0.48MgO + 7 | 1.72 | 1.24 | 1.48 | 1.72 | 1.72 | 2.20 | 1.84 | 1.96 |
| Density (g/cm³) | 2.52 | (2.52) | 2.58 | (2.59) | 2.58 | 2.54 | 2.55 | 2.56 |
| Average coefficient of thermal | 73 | (74) | (79) | (78) | (80) | 83 | 77 | 75 |
| expansion (×10⁻⁷/° C.) | | | | | | | | |
| Tg (° C.) | 655 | (652) | (655) | (655) | (665) | 651 | 652 | 652 |
| T₄ (° C.) | (1212) | (1211) | (1213) | (1220) | (1223) | (1212) | (1203) | (1211) |
| T₂ (° C.) | (1646) | (1641) | (1635) | (1639) | (1646) | (1637) | (1605) | (1614) |
| Devitrification temperature T_{L} | <1230 | <1230 | <1227 | <1236 | <1240 | <1227 | <1223 | <1231 |
| (° C.) | | | | | | | | |
| T₄ − T_{L} (° C.) | >−18 | >−19 | >−14 | >−16 | >−17 | >−15 | >−20 | >−20 |
| Brittleness index (m^{-1/2}) | 5850 | 6200 | (6050) | 6200 | (5950) | 6200 | 6250 | 6200 |
| Young's modulus (GPa) | (76.4) | (76.9) | (76.7) | (75.4) | (74.8) | (74.2) | (79.0) | (78.9) |
| Specific elastic modulus | (30.1) | (30.5) | (29.7) | (29.1) | (29.0) | (29.2) | (31.0) | (30.8) |
| (GPa · cm³/g) | | | | | | | | |
| Cell efficiency (%) (Condition | | | | | | | | |
| 1) | | | | | | | | |
| Voc (V) (Condition 1) | | | | | | | | |
| Jsc (mA/cm²) (Condition 1) | | | | | | | | |
| FF (Condition 1) | | | | | | | | |
| Cell efficiency (%) (Condition | 15.5 | | 13.6 | 14.4 | | 16.1 | 14.5 | 15.7 |
| 2) | | | | | | | | |
| Voc (V) (Condition 2) | 0.65 | | 0.67 | 0.67 | | 0.64 | 0.65 | 0.64 |
| Jsc (mA/cm²) (Condition 2) | 33.7 | | 28.0 | 30.0 | | 35.1 | 31.6 | 33.3 |
| FF (Condition 2) | 0.71 | | 0.73 | 0.72 | | 0.72 | 0.72 | 0.73 |
| Ca diffusion amount | | | | | | | | 240 |
| Na diffusion amount | | | | | | | | 10.7 |

TABLE 6

| Composition (mol %) | Ex. 36 | Ex. 37 | Ex. 38 | Ex. 39 | Ex. 40 | Ex. 41 | Ex. 42 |
|---|---|---|---|---|---|---|---|
| SiO₂ | 61.0 | 63.0 | 64.5 | 66.5 | 67.9 | 65.7 | 70.0 |
| Al₂O₃ | 9.0 | 9.5 | 5.5 | 4.7 | 5.0 | 4.5 | 1.5 |
| B₂O₃ | 0 | 0 | 0 | 0 | 0 | 0 | 0 |
| MgO | 15.5 | 9.5 | 11.5 | 3.4 | 1.0 | 7.3 | 6.0 |
| CaO | 2.5 | 2.5 | 7.0 | 6.2 | 12.0 | 7.3 | 7.0 |
| SrO | 1.0 | 0 | 0.5 | 4.7 | 1.0 | 1.0 | 0 |
| BaO | 0 | 0 | 1.0 | 3.6 | 0 | 0 | 0 |
| ZrO₂ | 0 | 2.0 | 1.5 | 1.7 | 1.5 | 2.2 | 2.5 |
| TiO₂ | 0 | 0 | 0 | 0 | 0 | 0 | 0 |
| Na₂O | 4.5 | 6.5 | 2.0 | 4.8 | 5.8 | 3.0 | 0.5 |
| K₂O | 6.5 | 7.0 | 6.5 | 4.4 | 5.8 | 9.0 | 12.5 |
| MgO + CaO + SrO + BaO | 19.0 | 12.0 | 20.0 | 17.9 | 14.0 | 15.6 | 13.0 |
| Na₂O + K₂O | 11.0 | 13.5 | 8.5 | 9.2 | 11.6 | 12.0 | 13.0 |
| MgO/Al₂O₃ | 1.72 | 1.00 | 2.09 | 0.72 | 0.20 | 1.62 | 3.92 |
| (2Na₂O + K₂O + SrO + BaO)/ | 1.83 | 1.74 | 1.71 | 3.48 | 2.83 | 2.39 | 3.35 |
| (Al₂O₃ + ZrO₂) | | | | | | | |
| Na₂O/K₂O | 0.69 | 0.93 | 0.31 | 1.09 | 1.00 | 0.33 | 0.04 |
| 2Na₂O + K₂O + MgO—CaO | 28.50 | 27.00 | 15.00 | 11.20 | 6.40 | 15.00 | 12.50 |
| MgO/(MgO + CaO + SrO + BaO) | 0.82 | 0.79 | 0.58 | 0.19 | 0.07 | 0.47 | 0.46 |
| -0.94MgO + 11 | −3.57 | 2.07 | 0.19 | 7.80 | 10.06 | 4.14 | 5.36 |
| -0.94MgO + 12 | −2.57 | 3.07 | 1.19 | 8.80 | 11.06 | 5.14 | 6.36 |
| -0.48MgO + 6.5 | −0.94 | 1.94 | 0.98 | 4.87 | 6.02 | 3.00 | 3.62 |
| -0.48MgO + 7 | −0.44 | 2.44 | 1.48 | 5.37 | 6.52 | 3.50 | 4.12 |
| Density (g/cm³) | 2.52 | 2.53 | 2.59 | 2.77 | (2.56) | (2.58) | (2.52) |
| Average coefficient of thermal | 82 | 86 | 74.0 | 83 | 84 | 86 | 88 |
| expansion (×10⁻⁷/° C.) | | | | | | | |
| Tg (° C.) | 664 | 667 | 678 | 620 | 631 | 642 | 664 |
| T₄ (° C.) | (1213) | (1252) | (1182) | 1136 | (1142) | (1177) | (1200) |
| T₂ (° C.) | (1633) | (1685) | (1573) | 1537 | (1566) | (1587) | (1628) |
| Devitrification temperature T_{L} (° C.) | >1263 | >1302 | >1230 | 1080 | >1200 | <1185 | >1215 |
| T₄ − T_{L} (° C.) | <−50 | <−50 | <−48 | 56 | <−58 | >−8 | <−15 |
| Brittleness index (m^{-1/2}) | 5900 | 5700 | (6100) | 7000 | (6450) | (6250) | (6350) |
| Young's modulus (GPa) | (78.2) | (74.6) | (78.6) | 76.0 | (73.6) | 75.2 | 68.5 |
| Specific elastic modulus | (31.0) | (29.5) | (30.3) | 27.4 | (28.8) | (30.0) | (27.3) |
| (GPa · cm³/g) | | | | | | | |
| Cell efficiency (%) (Condition 1) | | | | | 9.5 | 11.9 | 11.2 |
| Voc (V) (Condition 1) | | | | | 0.55 | 0.52 | 0.53 |
| Jsc (mA/cm²) (Condition 1) | | | | | 39.1 | 38.5 | 40.1 |
| FF (Condition 1) | | | | | 0.45 | 0.60 | 0.53 |
| Cell efficiency (%) (Condition 2) | | | | 13.7 | | | |
| Voc (V) (Condition 2) | | | | 0.67 | | | |
| Jsc (mA/cm²) (Condition 2) | | | | 28.8 | | | |
| FF (Condition 2) | | | | 0.72 | | | |
| Ca diffusion amount | | | | 316 | 533 | 389 | 550 |
| Na diffusion amount | | | | 28.1 | — | 5.9 | 2.2 |

As is apparent from Tables 1 to 5, the glass substrates of the examples (Examples 1 to 35) satisfy that T₄−T_{L} is −30° C. or higher, the glass transition temperature Tg is high as 640° C. or higher, the average coefficient of thermal expansion within the range of 50 to 350° C. is from 70×10⁻⁷ to 90×10⁻⁷/° C., and the density is 2.7 g/cm³ or less, and thus have the characteristics of a glass substrate for a CIGS solar cell in good balance.

Furthermore, in the glass substrates of the examples (Examples 1 to 35), the cell efficiency is high and the brittleness index is less than 7,000 m^{-1/2}.

Additionally, because the Ca diffusion amount is small and the Na diffusion amount is large as compared with the comparative examples (Examples 41 to 43), the growth of CIGS crystal is good, decrease in cell efficiency due to donor formation by diffusion of alkaline earth elements into the CIGS layer is difficult to occur, and the Na diffusion into the CIGS layer is sufficient. It is therefore considered that those lead to the enhancement in cell efficiency.

Regarding Mg, Sr and Ba, integral intensity in a molybdenum film was measured by secondary ion mass spectrometry (SIMS), similar to Ca and Na. Each of the integral intensity was the detection limit or less in the examples and the comparative examples.

Therefore, high cell efficiency, high glass transition temperature, given average coefficient of thermal expansion, high glass strength, low glass density, and devitrification prevention during manufacturing a sheet glass can all be satisfied. As a result, the CIGS photoelectric conversion layer does not peel from the glass substrate with the molybdenum film. Furthermore, in fabricating a solar cell in the present invention (specifically, in laminating a glass substrate having a CIGS photoelectric conversion layer and a cover glass by heating), the glass substrate is difficult to be deformed. Additionally, it is lightweight, devitrification does not occur, and cell efficiency is further excellent. Because T₂ is 1,650° C. or lower and T₄ is 1,230° C. or lower, meltability and formability during manufacturing a sheet glass are excellent.

On the other hand, as shown in Table 6, in the glass substrates of the comparative examples (Examples 36 to 38 and 40), T₄−T_{L} is lower than −30° C. and devitrification is easy to occur. Therefore, the glass substrates are difficult to be formed by float. It is considered that because Example 36 contains MgO in large amount, T_{L} is high, and because Examples 38 and 40 contain CaO in large amount, T_{L} is high. Furthermore, it is considered that because Example 37 has an inappropriate the value of MgO/Al₂O₃, T_{L} is high.

In the comparative example (Example 39), Tg is low, and a glass substrate is easy to change during the deposition at 600° C. or higher. Furthermore, it is considered that because Example 39 contains SrO and BaO in large amounts, the density is large and the brittleness index is high.

In the comparative examples (Examples 40 to 42), the cell efficiency is poor. This is considered to be due to that Ca diffusion amount is large, and Na diffusion amount is small.

The glass substrate for a Cu—In—Ga—Se solar cell of the present invention is suitable for a glass substrate and a cover glass of a solar cell of CIGS, and can be used for substrates or cover glasses for other solar cells.

While the invention has been described in detail and with reference to specific embodiments thereof, it will be apparent to one skilled in the art the various changes and modifications can be made therein without departing from the spirit and scope of the invention.

### INDUSTRIAL APPLICABILITY

The glass substrate for a Cu—In—Ga—Se solar cell of the present invention can have the characteristics of high cell efficiency, high glass transition temperature, a prescribed average coefficient of thermal expansion, high glass strength, low glass density, meltability and formability during production of a sheet glass, and prevention of devitrification in good balance. A solar cell having high cell efficiency can be provided by using the glass substrate for a CIGS solar cell of the present invention.

### EXPLANATIONS OF LETTER OR NUMERALS

1: Solar cell
5, 5a: Glass substrate
7, 7a: Plus electrode
9, 9a: CIGS layer
11, 11a: Buffer layer
13, 13a: Transparent conductive film
15, 15a: Minus electrode
16a: Minus terminal
17: Antireflection film
19: Cover glass

1. A glass substrate for a Cu—In—Ga—Se solar cell, containing, in terms of mol % on the basis of the following oxides:
from 60 to 75% of SiO₂;
from 1 to 7.5% of Al₂O₃;
from 0 to 1% of B₂O₃;
from 8.5 to 12.5% of MgO;
from 1 to 6.5% of CaO;
from 0 to 3% of SrO;
from 0 to 3% of BaO;
from 0 to 3% of ZrO₂;
from 0 to 3% of TiO₂;
from 1 to 8% of Na₂O; and
from 2 to 12% of K₂O,
wherein MgO+CaO+SrO+BaO is from 10 to 24%,
Na₂O+K₂O is from 5 to 15%,
MgO/Al₂O₃ is 1.3 or more,
(2Na₂O+K₂O+SrO+BaO)/(Al₂O₃+ZrO₂) is 3.3 or less,
Na₂O/K₂O is from 0.2 to 2.0
Al₂O₃≧−0.94MgO+11, and
CaO≧−0.48MgO+6.5,
wherein the glass substrate has a glass transition temperature of 640° C. or higher, an average coefficient of thermal expansion within a range of 50 to 350° C. of from 70×10⁻⁷ to 90×10⁻⁷/° C., a temperature (T₄) at which a viscosity reaches 10⁴ dPa·s of 1,230° C. or lower, a temperature (T₂) at which a viscosity reaches 10² dPa·s of 1,650° C. or lower, a relationship between the T₄ and a devitrification temperature (T_{L}) of T₄−T_{L}≧−30° C., and a density of 2.7 g/cm³ or less.

2. The glass substrate for a Cu—In—Ga—Se solar cell according to claim 1, containing, in terms of mol % on the basis of the following oxides:
from 62 to 73% of SiO₂;
from 1.5 to 7% of Al₂O₃;
from 0 to 1% of B₂O₃;
from 9 to 12.5% of MgO;
from 1.5 to 6.5% of CaO;
from 0 to 2.5% of SrO;
from 0 to 2% of BaO;
from 0.5 to 3% of ZrO₂;
from 0 to 3% of TiO₂;
from 1 to 7.5% of Na₂O; and
from 2 to 10% of K₂O,
wherein MgO+CaO+SrO+BaO is from 11 to 22%,
Na₂O+K₂O is from 6 to 13%,
MgO/Al₂O₃ is 1.4 or more,
(2Na₂O+K₂O+SrO+BaO)/(Al₂O₃+ZrO₂) is from 0.5 to 3,
Na₂O/K₂O is from 0.4 to 1.7
Al₂O₃≧−0.94MgO+12, and
CaO≧−0.48MgO+7,
wherein the glass substrate has the glass transition temperature of 645° C. or higher, the average coefficient of thermal expansion within a range of 50 to 350° C. of from 70×10⁻⁷ to 85×10⁻⁷/° C., the temperature (T₄) at which a viscosity reaches 10⁴ dPa·s of 1,220° C. or lower, the temperature (T₂) at which a viscosity reaches 10² dPa·s of 1,630° C. or lower, the relationship between the T₄ and a devitrification temperature (T_{L}) of T₄−T_{L}≧−20° C., and the density of 2.65 g/cm³ or less.

3. The glass substrate for a Cu—In—Ga—Se solar cell according to claim 1, wherein MgO/(MgO+CaO+SrO+BaO) is from 0.4 to 0.9.

4. The glass substrate for a Cu—In—Ga—Se solar cell according to claim 2, wherein MgO/(MgO+CaO+SrO+BaO) is from 0.4 to 0.9.

5. A solar cell, comprising a glass substrate, a cover glass, and a photoelectric conversion layer of Cu—In—Ga—Se provided between the glass substrate and the cover glass,
wherein at least the glass substrate of the glass substrate and the cover glass is the glass substrate for a Cu—In—Ga—Se solar cell according to claim 1.

6. A solar cell, comprising a glass substrate, a cover glass, and a photoelectric conversion layer of Cu—In—Ga—Se provided between the glass substrate and the cover glass,
wherein at least the glass substrate of the glass substrate and the cover glass is the glass substrate for a Cu—In—Ga—Se solar cell according to claim 2.

7. A solar cell, comprising a glass substrate, a cover glass, and a photoelectric conversion layer of Cu—In—Ga—Se provided between the glass substrate and the cover glass,
wherein at least the glass substrate of the glass substrate and the cover glass is the glass substrate for a Cu—In—Ga—Se solar cell according to claim 3.

8. A solar cell, comprising a glass substrate, a cover glass, and a photoelectric conversion layer of Cu—In—Ga—Se provided between the glass substrate and the cover glass,
wherein at least the glass substrate of the glass substrate and the cover glass is the glass substrate for a Cu—In—Ga—Se solar cell according to claim 4.
